(19) United States
(12) Patent Application Publication
(10) Pub. No.: US 2022/0223486 A1
(43) Pub. Date: Jul. 14, 2022

(54) SEMICONDUCTOR PACKAGES WITH ENGAGEMENT SURFACES

(71) Applicant: TEXAS INSTRUMENTS INCORPORATED, Dallas, TX (US)

(72) Inventors: Tobias Bernhard FRITZ, Mainburg (DE); Baher S. HAROUN, Allen, TX (US); Benjamin Stassen COOK, Los Gatos, CA (US); Michael SZELONG, Freising (DE); Ernst MUELLNER, Muenchen (DE); Jeronimo SEGOVIA-FERNANDEZ, San Jose, CA (US)

(21) Appl. No.: 17/538,850

(22) Filed: Nov. 30, 2021

Related U.S. Application Data
(60) Provisional application No. 63/136,236, filed on Jan. 12, 2021.

(51) Int. Cl. H01L 23/13; H01L 23/31; H01L 23/495; G01L 1/18

(52) U.S. Cl. CPC H01L 23/13; H01L 23/3121; H01L 23/49503; H01L 24/48; H01L 2224/04; H01L 2224/48175; G01L 1/18

(57) ABSTRACT

An example semiconductor package includes a semiconductor die configured to detect a force. In addition, the semiconductor package includes a mold compound covering the semiconductor die. Further, the semiconductor package includes an engagement surface including a pattern of projections adapted to engage with a mounting surface on a member of interest.

### CROSS-REFERENCE TO RELATED APPLICATIONS

The present application claims priority to U.S. Provisional Patent Application No. 63/136,236, which was filed Jan. 12, 2021, is titled “Structured Layers Inside Packages And On Surfaces For Improved Mechanical Force Coupling,” and is hereby incorporated herein by reference in its entirety.

### BACKGROUND

Force sensors are useful to detect one or more forces experienced by a member of interest. In some instances, a force sensor may be useful to detect stress, torque, compression, strain, tension, etc. experienced by the member of interest (e.g., a shaft, strut, beam). To facilitate the detection of these forces, the force sensor (or some component thereof) is mounted to the member so forces experienced by the member may be transferred to the force sensor during operations.

### SUMMARY

Some examples described herein include a semiconductor package. In some examples, the semiconductor package includes a semiconductor die configured to detect a force. In addition, the semiconductor package includes a mold compound covering the semiconductor die. Further, the semiconductor package includes an engagement surface including a pattern of projections adapted to engage with a mounting surface on a member of interest.

In some example, the semiconductor package includes a die pad having a first side and a second side opposite the first side. In addition, the semiconductor package includes a semiconductor die mounted to the first side of the die pad, the semiconductor die being configured to detect a force. The second side of the die pad includes a pattern of projections that are adapted to engage a pattern of recesses in a mounting surface of a member of interest.

In some examples, the semiconductor package includes a die pad and a semiconductor die mounted to the die pad. In addition, the semiconductor package includes a mold compound having a first side and a second side opposite the first side. The compound covers the die pad and the semiconductor die, and the second side includes a pattern of projections that are adapted to engage with a mounting surface on a member of interest.

### BRIEF DESCRIPTION OF THE DRAWINGS

FIG. 1A is a side cross-sectional view of a force sensor for mounting to a member of interest according to some examples.

FIG. 1B is a bottom view of a force sensor for mounting to a member of interest according to some examples.

FIG. 1C is an enlarged cross-sectional view of an engagement surface of the force sensor and mounting surface of a member of interest according to some examples.

FIG. 2A is a bottom view of a force sensor for mounting to a member of interest according to some examples.

FIG. 2B is a bottom view of a force sensor for mounting to a member of interest according to some examples.

FIG. 2C is a bottom view of a force sensor for mounting to a member of interest according to some examples.

FIG. 3 is a side cross-sectional view of a force sensor for mounting to a member of interest according to some examples.

FIG. 4A is a side cross-sectional view of a force sensor for mounting to a member of interest according to some examples.

FIG. 4B is a bottom view of a force sensor for mounting to a member of interest according to some examples.

FIG. 5A is side cross-sectional view of a force sensor for mounting to a member of interest according to some examples.

FIG. 5B is a side cross-sectional view of a force sensor for mounting to a member of interest according to some examples.

FIG. 6A is side cross-sectional view of a force sensor for mounting to a member of interest according to some examples.

FIG. 6B is side cross-sectional view of a force sensor for mounting to a member of interest according to some examples.

FIG. 7 is a side cross-sectional view of a force sensor for mounting to a member of interest according to some examples.

### DETAILED DESCRIPTION

A force sensor may be mounted to a member of interest for detecting (e.g., directly, indirectly) forces within the member. The force sensor is mounted to the member of interest, and forces experienced by the member may be transferred to the force sensor via the mounting. Some mounting devices or techniques may dampen or absorb forces that are transferred from the member of interest thereby causing the force sensor to be less effective at detecting these forces during operations. Thus, mounting the force sensor to the member of interest may have a meaningful effect on the quality of data that may be obtained by the force sensor during operations.

In some instances, a force sensor may be useful for detecting forces in a particular direction along a surface of the member of interest. However, some mounting techniques may not allow a force sensor to adequately detect these targeted forces or force directions. Accordingly, examples described herein include force sensors that include projections on an engagement surface that are to engage with a mounting surface of a member of interest. The engagement of the projections with the mounting surface may amplify particular forces or force directions during operations.

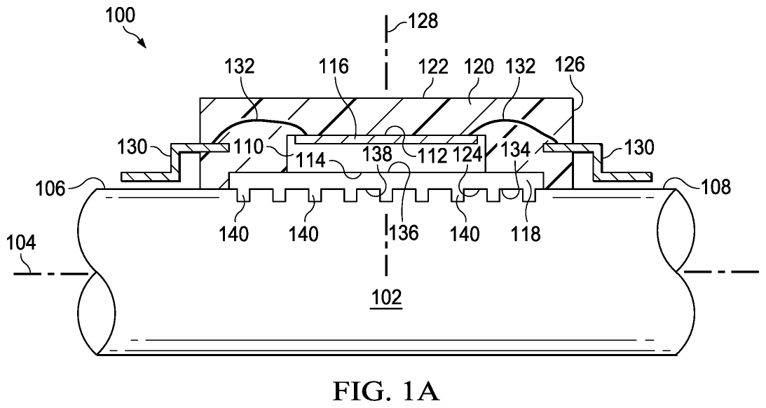

Referring now to FIG. 1A, a force sensor 100 according to some examples is shown mounted to a shaft 102 that is rotatable about a central or longitudinal axis 104. The shaft 102 may be a rotating shaft of a pump, compressor, drivetrain or other mechanical system. The force sensor 100 is mounted to a mounting surface 106 which may include a planar or facetted surface that is defined on the otherwise curved outer surface 108 of shaft 102. In some examples, the force sensor 100 may be mounted to another member of interest, such as, for instance, a beam, column, hinge, wing (or air foil), rotor blade, or any other mechanical or structural member that may experience forces during operations.

During operations, the force sensor 100 may detect, via the engagement with mounting surface 106, the forces experienced by the shaft 102. For instance, the shaft 102 may experience a torque about longitudinal axis 104, axial stress (e.g., from tension or compression along longitudinal axis 104), bending stress, strain, etc. These various forces and stresses that may be experienced by the shaft 102 may be collectively and generally referred to herein as “forces.” The force sensor 100 may detect (e.g., directly or indirectly) any one or more of these forces during operations thereby allowing personnel to monitor the operating conditions of the shaft 102.

The force sensor 100 is a semiconductor package that includes a semiconductor die 110. Accordingly, the force sensor 100 may be referred to herein as a “semiconductor package.” The semiconductor die 110 has a device side 112 and non-device side 114 opposite the device side 112. An active circuit 116 (or more simply “circuit 116”) is formed on the device side 112. The non-device side 114 of semiconductor die 110 is secured to a die pad 118 via a die attach layer (not shown).

A mold compound 120 (e.g., a polymer or resin material) may cover the semiconductor die 110 and die pad 118. The mold compound 120 may protect the semiconductor die 110 and die pad 118 from the outside environment (e.g., specifically from dust, liquid, light, contaminants in the outside environment), and may prevent undesired contact with conductive surfaces or members during operations. As referred to herein, the term “mold compound” includes a covering for a semiconductor die that is formed through any suitable process, such as a cavity molding operation, glob encapsulation, dam-and-fill type encapsulation, etc. The mold compound 120 may include a first side 122, a second side 124 opposite first side 122, and an outer perimeter 126 extending between the first side 122 and the second side 124 along an axis 128 that extends through (e.g., perpendicularly through) the sides 122, 124.

The circuit 116 may be coupled to conductive terminals 130 via bond wires 132. In some examples, the conductive terminals 130 may be so-called gull-wing leads. However, the force sensor 100 may include a quad flat no-lead (QFN) package and the conductive terminals 130 may be arranged and designed for inclusion therein. The conductive terminals 130 may be coupled to suitable connectors on a printed circuit board (PCB) (not shown) or other suitable device. The mold compound 120 may cover the bond wires 132 and a portion of the conductive terminals 130.

Referring now to FIGS. 1A-1C, the force sensor 100 may also include an engagement surface 134 that is defined by the die pad 118 and that is to engage with the mounting surface 106 of shaft 102. More particular, the die pad 118 includes a first side 136 that is engaged with the semiconductor die 110 and a second side 138 opposite first side 136. The second side 138 may be flush (or co-planar) with the second side 124 of mold compound 120. The engagement surface 134 is defined on the second side 138. In some examples, the engagement surface 134 includes a pattern of projections 140 that are to engage with mounting surface 106 during operations.

As best shown in FIGS. 1B and 1C, the projections 140 may be parallel to one another. Also, the projections 140 may be spaced from one another along a plane that is aligned with a radius of axis 128. Thus, the projections 140 may be radially spaced from one another with respect to axis 128. The projections 140 and second side 138 of die pad 118 may be contained within (or bounded by) the outer perimeter 126 of mold compound 120.

As is best shown in FIG. 1C, in some examples the mounting surface 106 may have a pattern of recesses 142 that may be aligned with and that may receive the projections 140 on second side 138 during operations. The second side 138 and mounting surface 106 are shown separated from one another along axis 128 in FIG. 1C, to better show the projections 140 and recesses 142. The shape, size, and arrangement of the recesses 142 may be chosen to allow recesses 142 to align, engage, and interlock with projections 140 upon contact of second side 138 with mounting surface 106. Thus, the recesses 142 may be spaced from one another along a plane that is aligned with a radius of axis 128, and the recesses 142, like projections 140, may be radially spaced from one another with respect to axis 128.

In some examples, the projections 140 may each include a crest 144 that is spaced (e.g., axially spaced with respect to axis 128) from second side 138, and a pair of flanks 146 that extend from the crest 144 to the second side 138. Likewise, each recess 142 may each include a root 148 that is inwardly spaced from mounting surface 106, and a pair of flanks 150 that extend from the mounting surface 106 to the root 148. In some examples, each projection 140 and each recess 142 may have a rectangular cross-section. Therefore, the crest 144 and root 148 of each projection 140 and recess 142, respectively, may be a planar surface that is oriented radially relative to axis 128. Also, each of the flanks 146 may extend perpendicularly (e.g., axially with respect to axis 128) to the crest 144 from the second side 138, and each of the flanks 150 may extend perpendicularly (e.g., axially with respect to axis 128) to the root 148 from the mounting surface 106. In some examples, the cross-sections of projections 140 and recesses 142 may have a variety of shapes, such as triangular, semicircular, oval, ovoid, truncated triangle, etc.

During operations, as engagement surface 134 of force sensor 100 is brought into contact with mounting surface 106, the projections 140 are inserted within recesses 142. In some examples, the engagement surface 134 is engaged with the mounting surface 106 via an adhesive or solder material. In some examples, the engagement surface 134 is welded (e.g., via ultrasonic welding) to the mounting surface 106.

After force sensor 100 is secured to mounting surface 106, forces experienced by the shaft 102 may be transferred to the circuit 116 via the engagement between the pattern of projections 140 on engagement surface 134 and mounting surface 106. The semiconductor die 110 may be configured to detect the transferred forces. In particular, the circuit 116 of semiconductor die 110 may detect the transferred forces via piezoresistive changes caused in the circuit 116 by the forces. The circuit 116 may also produce an output signal that includes (or is indicative of) the detected force(s). In some examples, the force sensor 100 may include additional components (e.g., semiconductor dies, passive components such as antennas, capacitors, resistors, etc.) that may process the output from the circuit 116 and/or communicate the output from the circuit 116 to other electronic devices (e.g., computers, semiconductor packages). As is described in more detail below, the projections 140 on engagement surface 134 may facilitate a strong connection between the shaft 102 and force sensor 100 and may amplify forces in particular directions (e.g., such as a direction that is perpendicular to the projections 140 and recesses 142).

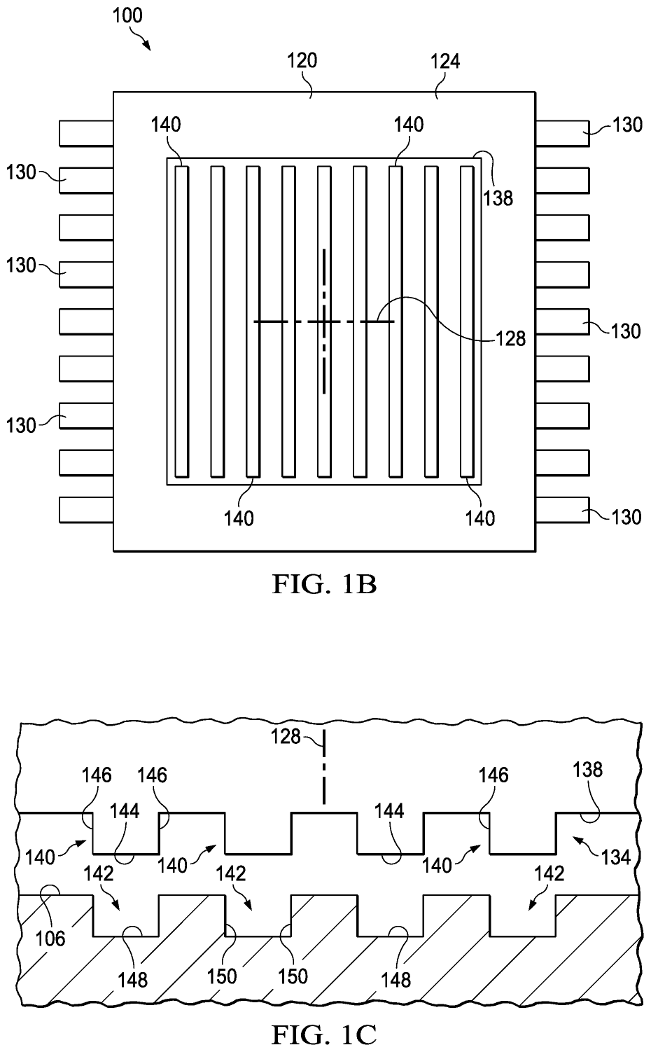

Referring now to FIGS. 2A-2C, force sensors 200 that may each be the force sensor 100 of FIG. 1A-1C are shown according to some examples. FIGS. 2A-2C may be collectively referred to herein as “FIG. 2.”

In FIGS. 2A-2C, the force sensors 200 may be semiconductor packages. Accordingly, the force sensors 200 may be referred to herein as “semiconductor packages.” The force sensors 200 each may include a die pad 202 that is flush (or co-planar) with a side 204 of a mold compound 206. A semiconductor die (not shown) may be coupled to the die pad 202 and covered by the mold compound 206 as described above for force sensor 100. The mold compound 206 includes an outer perimeter 208 that includes multiple sides 209. Also, force sensors 200 may include multiple conductive terminals 210 that extend out of one or more sides 209 of the outer perimeter 208 of mold compound 206.

The die pad 202 (or an exposed side thereof) may define an engagement surface 212 of the force sensor 200 that is to engage with a mounting surface on a member of interest (e.g., mounting surface 106 on shaft 102 in FIG. 1A). The engagement surface 212 may include a pattern of projections 214 that may be similar to the projections 140 described above for force sensor 100.

Referring specifically to FIG. 2A, in some examples the outer perimeter 208 of the mold compound 206 may be generally rectangular in shape, and thus opposing sides 209 of the outer perimeter 208 may be parallel to one another. Also, the projections 214 may extend linearly in a direction that is perpendicular to two opposing sides 209 of outer perimeter 208 of mold compound 206. Without being limited to this or any other theory, the orientation of the projections 214 in FIG. 2A may provide additional sensitivity to force sensor 200 for forces that are directed along a direction that is perpendicular to the projections 214.

Referring specifically to FIGS. 2B and 2C, in some examples the projections 214 may extend across die pad 202 at a non-zero, nonparallel, and non-perpendicular angles to each of the sides 209. Accordingly, in the examples of FIGS. 2B and 2C, the projections 214 do not extend perpendicularly or parallel to any of the sides 209 of outer perimeter 208. Without being limited to this or any other theory, by placing the projections 214 at an angle across the die pad 202, the force sensor 200 may have sensitivity to forces directed along a pair of perpendicular or orthogonal directions across the side 204 of mold compound 206. Accordingly, the force sensors 200 of FIGS. 2B and 2C may have multidirectional sensitivity in a plane extending parallel to the side 204 of mold compound 206.

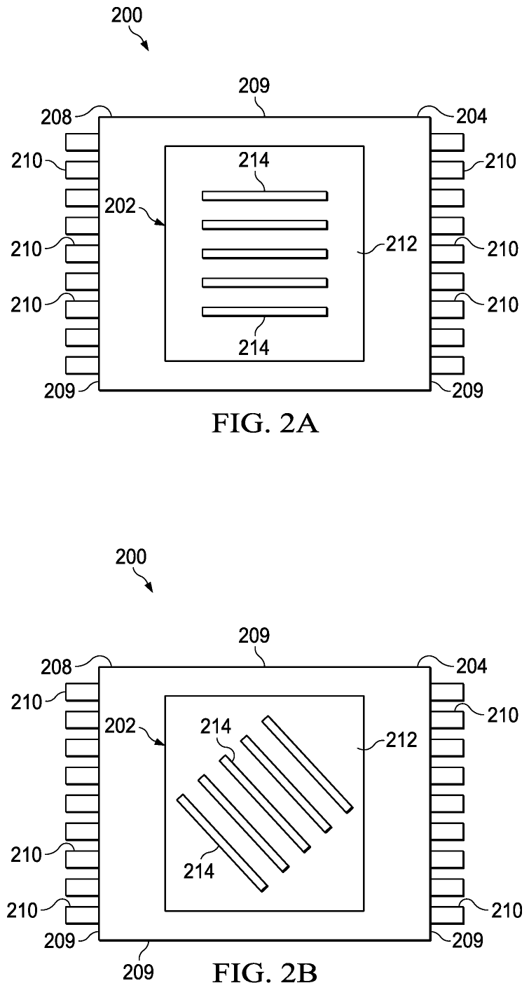

Referring now to FIG. 3, a force sensor 300 that may be the force sensor 100 of FIG. 1 is shown according to some examples. The force sensor 300 is a semiconductor package that includes a semiconductor die 302. Accordingly, the force sensor 300 may be referred to herein as a “semiconductor package.” The semiconductor die 302 has a device side 304 and non-device side 306 opposite the device side 304. An active circuit 308 (or more simply “circuit 308”) is formed on the device side 304. The non-device side 306 of semiconductor die 302 is secured to a die pad 309 via a die attach layer (not shown).

A mold compound 310 (e.g., a polymer or resin material) may cover the semiconductor die 302 and die pad 309. The mold compound 310 may protect the semiconductor die 302 and die pad 309 from the outside environment (e.g., specifically from dust, liquid, light, contaminants in the outside environment), and may prevent undesired contact with conductive surfaces or members during operations. The mold compound 310 may include a first side 312, a second side 314 opposite first side 312, and an outer perimeter 316 extending between the first side 312 and the second side 314 along an axis 318 that extends through (e.g., perpendicularly through) the sides 312, 314. Multiple conductive terminals 320 may extend out of the outer perimeter 316 of mold compound 310 and may be coupled to circuit 308 of semiconductor die 302 via bond wires 322.

The force sensor 300 may also include an engagement surface 324 that is defined by the second side 314 of mold compound 310 that is to engage with the mounting surface 326 of member 328 of interest (e.g., shaft 102). More particularly, the die pad 309 is recessed into the mold compound 310. Thus, die pad 309 is fully covered by mold compound 310, and engagement surface 324 is defined by the second side 314 of mold compound 310.

In some examples, the engagement surface 324 includes a pattern of projections 330 that are to engage with mounting surface 326 during operations. The projections 330 may be similar to the projections 140 described above. In some examples, the projections 330 may engage with similarly shaped recesses 332 that are defined on mounting surface 326 in a similar manner to that described above for projections 140 and recesses 142 (FIG. 1C).

During operations, the engagement surface 324 may be secured to the mounting surface 326 of member 328 of interest via adhesive, solder material, welding, or any other suitable manner. The interconnection between the projections 330 and recesses 332 may amplify forces in a particular direction (e.g., such as a direction that is applied in a direction that is perpendicular to the projections 330 and recesses 332).

The semiconductor die 302 may be configured to detect forces experienced by the member 328 of interest via the connection between the projections 330 on engagement surface 324 and the recesses 332 on the mounting surface 326. Specifically, the circuit 308 of semiconductor die 302 may detect the forces via piezoresistive changes and may produce an output signal that includes (or is indicative of) the detected forces as described above. The force sensor 300 may include additional components for communicating and/or processing the output from circuit 308 during operations as described above.

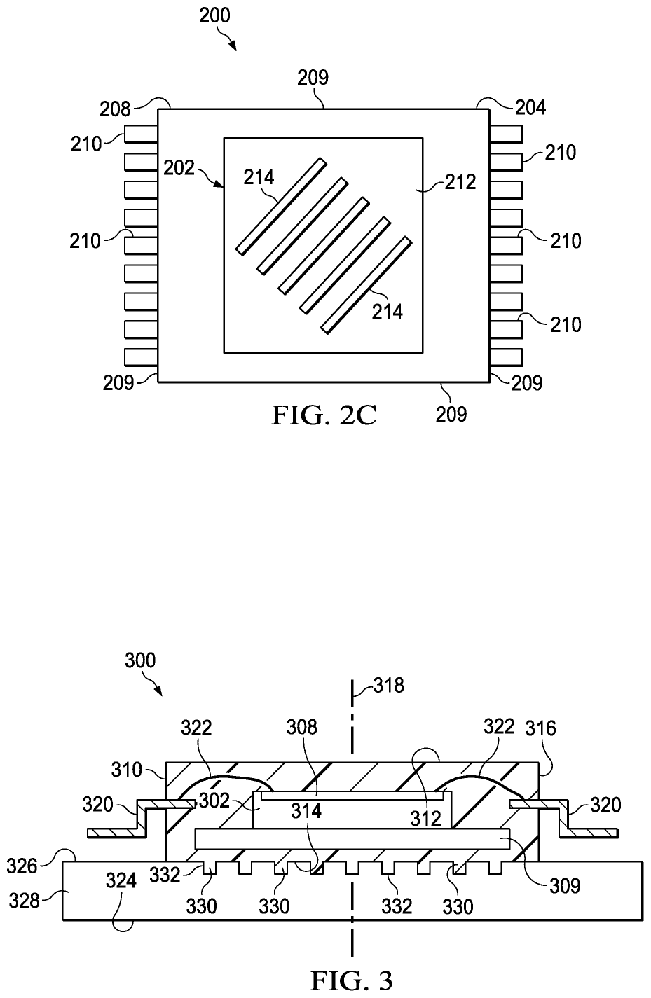

Referring now to FIGS. 4A and 4B, a force sensor 400 that may be the force sensor 100 of FIG. 1 is shown according to some examples. The force sensor 400 is a semiconductor package that includes a semiconductor die 402. Accordingly, the force sensor 400 may be referred to herein as a “semiconductor package.” The semiconductor die 402 has a device side 404 and non-device side 406 opposite the device side 404. An active circuit 408 (or more simply “circuit 408”) is formed on the device side 404.

The non-device side 406 defines an engagement surface 409 that is to engage with a mounting surface 410 of a member 412 of interest (e.g., shaft 102 in FIG. 1). In some examples, the engagement surface 409 includes a pattern of projections 414 that are to engage with mounting surface 410 during operations.

As best shown in FIG. 4B, the projections 414 are arranged in multiple rows 416 and columns 418 across the non-device side 406 of semiconductor die 402. In some examples, the projections 414 may be shaped as truncated pyramids. However, in other examples the projections 414 may have other shapes such as rectangular parallelepiped, spherical, semispherical, etc. The projections 414 may be formed on non-device side 406 via a sputtering and plating process.

A number of passive devices 420 are coupled to the circuit 408 along device side 404. The passive devices 420 may be coupled to circuit 408 via solder members 422 (which may be referred to as “solder bumps”). In some examples, the passive devices 420 may include capacitors, inductors, antennas, coils and/or other components that may perform a function (or functions) either independently of or along with circuit 408. In some examples, the passive devices 420 may include an antenna and a filter that are coupled to circuit 408 and that are configured to receive and/or send wireless electronic signals to other devices (e.g., computers, semiconductor chip packages) either directly or via a network. Specifically, during operations, the antenna, formed or defined by the passive devices 420, may transmit output signals of the force sensor 400 that may include, or be indicative of, forces detected by the force sensor 400.

Referring specifically to FIG. 4A, during operations, the engagement surface 409 may be coupled to the mounting surface 410. In particular, the projections 414 of engagement surface 409 may engage and/or mesh with a set of projections 424 positioned along the mounting surface 410. In some examples, the projections 424 on mounting surface 410 may be similarly shaped as the projections 414 on engagement surface 409. The projections 424 may be arranged to be positioned between adjacent projections 414 on engagement surface 409. Accordingly, the projections 424 may be interleaved between projections 424 upon securing engagement surface 409 to mounting surface 410. Without being limited to this or any other theory, the interleaving of the projections 424, 414 may allow forces to transfer from the member 412 of interest to the force sensor 400 along a plane that passes through the projections 424, 414.

In some examples, the force sensor 400 may be secured to the member 412 of interest via solder material 426 (e.g., a metallic material that may be melted and re-solidified to bond two objects or members together). The solder material 426 may form a bond between the engagement surface 409 and the mounting surface 410 and between the interleaved projections 414, 424. Accordingly, during operations, forces experienced by the member 412 of interest may be transferred from the mounting surface 410 to the force sensor 400 via the projections 424, solder material 426 and projections 414. The engagement of projections 414, 424 via solder material 426 may provide a secure contact between the force sensor 4300 and the member 412 while allowing force detection sensitivity in multiple directions.

The solder material 426 may be bonded to the engagement surface 409 (including the projections 414, 424) by any suitable manner. For instance, localized heat may be applied to melt the solder material 426 and allow it to flow between the projections 414, 424. In some example, the solder material 426 may be placed between the engagement surface 409 and the mounting surface 410, and then the force sensor 400, member 412, and solder material 426 may be placed in an environment having an elevated temperature (e.g., an oven, chamber). The elevated heat of the surrounding environment may cause the solder material 426 to melt and flow between the projections 414, 424.

The semiconductor die 402 may be configured to detect forces experienced by the member 412 of interest via the connection between the projections 414 and 424 on engagement surface 324 and mounting surface 410, respectively. Specifically, the circuit 408 of semiconductor die 402 may detect the forces via piezoresistive changes and may produce an output signal that includes (or is indicative of) the detected forces as described above. The passive components 420 may then communicate and/or process the output from circuit 408 during operations as described above.

In some examples, the semiconductor die 402 may be mounted to a die pad. Accordingly, the die pad may define the engagement surface 409 having the projections 414 in some examples.

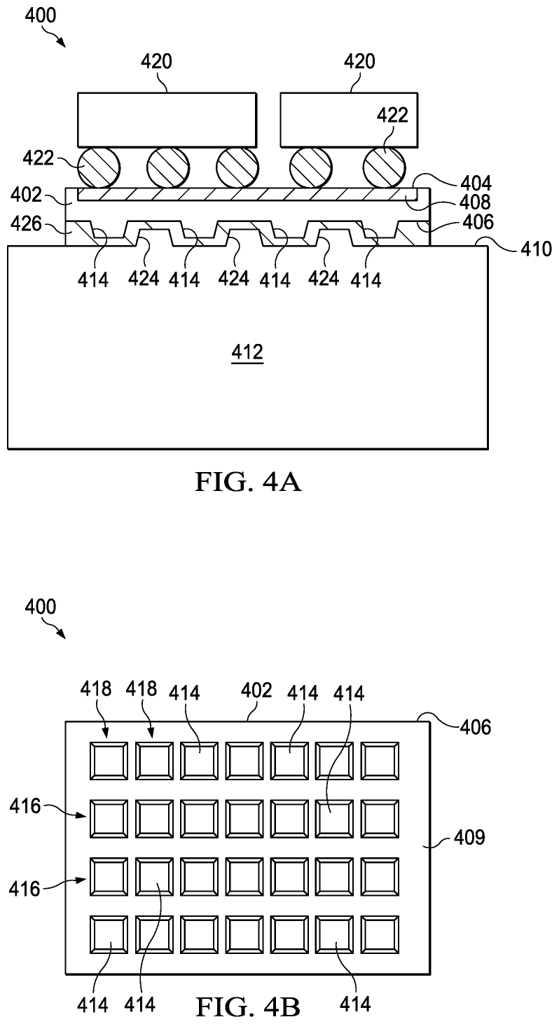

Referring now to FIGS. 5A and 5B, force sensors 500 that may be the force sensor 100 of FIG. 1 are shown according to some examples. The force sensors 500 are semiconductor packages that each include a semiconductor die 502. Accordingly, the force sensors 500 may be referred to herein as “semiconductor packages.” The semiconductor die 502 has a device side 504 and non-device side 506 opposite the device side 504. An active circuit 508 (or more simply “circuit 508”) is formed on the device side 504.

The non-device side 506 defines an engagement surface 509 that is to engage with a mounting surface of a member of interest (e.g., mounting surface 106 of shaft 102 in FIG. 1). In some examples, the engagement surface 509 includes a pattern of projections 514 that are similar to the projections 414 described above for force sensor 400.

A number of passive devices 520 are coupled to the circuit 508 of semiconductor die 502. In the example of FIG. 5A, the passive devices 520 may be coupled to circuit 508 via solder members 522 (which may be referred to as “solder bumps”). In the example of FIG. 5B, the passive devices 520 are coupled to circuit 508 via a redistribution layer 524. In particular, the redistribution layer 524 is a conductive member that selectively couples the passive devices 520 to the circuit 508 (or particular parts thereof). The passive devices 520 may be coupled to the redistribution layer 524 via multiple conductive members 526 that may be engaged (e.g., soldered) to the redistribution layer 524, and in turn, the redistribution layer 524 is coupled to the circuit 508 via solder members 522.

In some examples, the passive devices 520 may be similar to the passive devices 420 described above for force sensor 400. Thus, during operations, the passive devices 520 may perform the same function(s) described above for the passive devices 420.

The force sensors 500 both also include a mold compound 530 (e.g., a polymer or resin material) may cover the semiconductor die 502. The mold compound 530 may protect the semiconductor die 502 from the outside environment (e.g., specifically from dust, liquid, light, contaminants in the outside environment), and may prevent undesired contact with conductive surfaces or members during operations. The mold compound 530 may include a first side 532, a second side 534 opposite first side 532, and an outer perimeter 536 extending between the first side 532 and the second side 534 along an axis 538 that extends through (e.g., perpendicularly through) the sides 532, 534. In FIG. 5A, the second side 534 of mold compound 530 is engaged with device side 504 of semiconductor die 502. In FIG. 5B, the second side 534 of mold compound 530 is flush (or coplanar) with the non-device side 506 of semiconductor die 502.

During operations, the engagement surface 509 may be secured to a mounting surface of a member of interest (e.g., mounting surface 106 on shaft 102 in FIG. 1). In some examples, the engagement surface 509 may be engaged with a mounting surface of a member of interest via a solder material (e.g., solder material 426 described above). Also, in some examples the projections 514 may be interleaved with projections (e.g., projections 424 described above) on the mounting surface in a similar manner to that described above for force sensor 500. During operations, forces experienced by the member of interest may be transferred to the force sensor 500 via the projections 514 on engagement surface 509.

The semiconductor die 502 may be configured to detect forces experienced by the member of interest via the connection therebetween. Specifically, the circuit 508 of semiconductor die 502 may detect the forces via piezoresistive changes and may produce an output signal that includes (or is indicative of) the detected forces as described above. The passive components 520 may then communicate and/or process the output from circuit 508 during operations as described above.

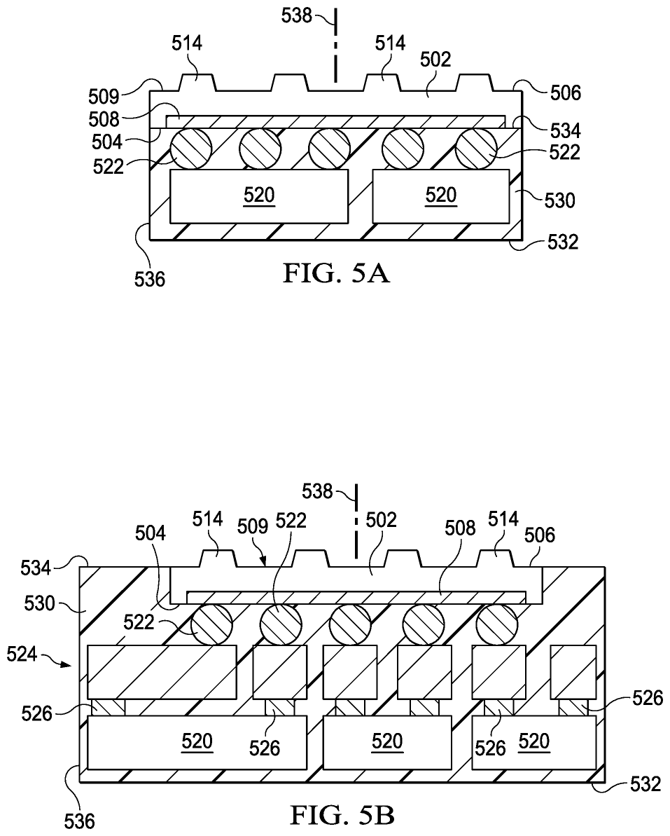

Referring now to FIGS. 6A and 6B, force sensors 600 that may be the force sensor 100 of FIG. 1 are shown according to some examples. The force sensors 600 are semiconductor packages that each include a semiconductor die 602. Accordingly, the force sensors 600 may each be referred to herein as a “semiconductor package.” The semiconductor die 602 of each force sensor 600 has a device side 604 and non-device side 606 opposite the device side 604. An active circuit 608 (or more simply “circuit 608”) is formed on the device side 604. The non-device side 606 of semiconductor die 602 is secured to a die pad 609 via a solder paste (not shown).

The force sensors 600 may also include an engagement surface 610 that is defined by the die pad 609 that is to engage with a mounting surface 612 of a member 614 of interest. More particularly, the die pad 609 includes a first side 616 that is engaged with the semiconductor die 602 and a second side 618 opposite first side 616. The engagement surface 610 is defined on the second side 618. In some examples, the engagement surface 610 includes a pattern of projections 620 that are similar to the projections 140 of force sensor 100 describe above.

During operations, the projections 620 may engage with the mounting surface 612 so as to maintain a spacing D between the second side 618 of die pad 609 and the mounting surface 612. Referring specifically to FIG. 6A, in some examples the mounting surface 612 may be a substantially planar and the spacing D may be defined by a length of the projections 620 from the second side 618. Referring specifically to FIG. 6B, in some examples the mounting surface 612 may include a number of recesses 622 that are to receive the projections 620 therein (e.g., in a similar manner to the recesses 142 on mounting surface 106 described above and shown in FIGS. 1A and 1C), and the spacing D may be defined as the difference between the length of projections 614 from second side 618 and the depth of recesses 622 from mounting surface 612. In either case, the spacing D may be chosen to provide sufficient clearance between the second side 618 and mounting surface 612 to receive adhesive, solder, etc. therein. In some examples, the spacing D may be chosen to elevate the force sensor 600 above the mounting surface 612 to prevent forces from transferring to the force sensor 600 from the member 614 of interest via pathways other than through engagement surface 610 (including projections 612). In some examples, the spacing D may range from a few micrometers to a few millimeters. In some examples, the spacing D may allow projections 620 to dampen (or buffer) forces over a magnitude, to reduce damage to the force sensor 600 or components thereof.

The semiconductor die 602 may be configured to detect forces experienced by the member 614 of interest via the connection therebetween. Specifically, the circuit 608 of semiconductor die 602 may detect the forces via piezoresistive changes and may produce an output signal that includes (or is indicative of) the detected forces as described above.

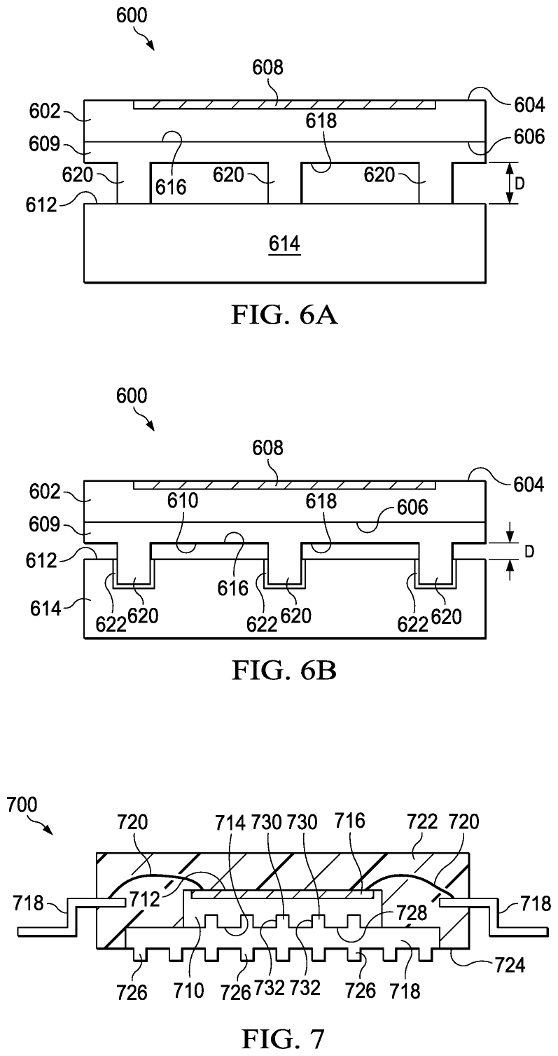

Referring now to FIG. 7, a force sensor 700 that may be the force sensor 100 of FIG. 1A-1C is shown according to some examples. The force sensor 700 is a semiconductor package that includes a semiconductor die 710. Accordingly, the force sensor 700 may be referred to herein as a “semiconductor package.” The semiconductor die 710 has a device side 712 and non-device side 714 opposite the device side 712. An active circuit 716 (or more simply “circuit 716”) is formed on the device side 712. The circuit 716 may be coupled to conductive terminals 718 via bond wires 720 in a similar manner to that described above for conductive terminals 130 and bond wires 132 of force sensor 100 (FIG. 1A).

A mold compound 722 (e.g., a polymer or resin material) may cover the semiconductor die 710 and die pad 718. The mold compound 722 may protect the semiconductor die 710 and die pad 718 from the outside environment (e.g., specifically from dust, liquid, light, contaminants in the outside environment), and may prevent undesired contact with conductive surfaces or members during operations.

The force sensor 700 may also include a first engagement surface 724 that is defined by the die pad 718 and that is to engage with a mounting surface of a member of interest (e.g., shaft 102 in FIG. 1A). The first engagement surface 724 may be similar to the engagement surface 134 described above for force sensor 100. Thus, the first engagement surface 724 may include a pattern of projections 726 that are to engage with a mounting surface on a member of interest during operations in a similar manner to that described above for projections 140.

In addition, force sensor 700 may include a second engagement surface 728 on the die pad 718 on a side of the die pad 718 that is opposite from the first engagement surface 724. The second engagement surface 728 may include a pattern of projections 730 that are similar to the projections 140 described above (FIGS. 1A-1C). The projections 730 may engage and interlock with a pattern of recesses 732 formed on the non-device side 714 of semiconductor die 710 in a similar manner to the engagement described above for projections 140 and recesses 142 (FIG. 1C). In some examples, the projections 730 may be formed on the non-device side 714 of semiconductor die 710 and the recesses 732 may be formed on the die pad 718.

During operations, the second engagement surface 728 may enhance force transfer from the die pad 718 to the semiconductor die 718 (and ultimately to circuit 716). As described above, the engaged projections 730 and recesses 732 may facilitate a strong connection between the semiconductor die 710 and die pad 718 and may amplify forces in particular directions (e.g., such as a direction that is perpendicular to the projections 730 and recesses 732).

The examples described above include force sensors that include patterned projections that are to engage with a mounting surface of a member of interest and amplify particular forces or force directions during operations. Thus, the projections formed on the engagement surface of the example force sensors described herein may enhance the connection of the force sensor to the member of interest and the sensitivity of the force sensor for detecting forces of interest during operations.

While examples described herein have included semiconductor packages that function as force sensors (e.g., forces sensors 100, 200, 300, 400, 500, 600, 700), some examples described herein may include semiconductor packages that provide additional and/or different functionality (e.g., other than force sensing). Thus, generally speaking, examples described herein may include semiconductor packages having engagement surfaces as described herein that may be mounted to a suitable member or surface.

In this description, the term “couple” may cover connections, communications or signal paths that enable a functional relationship consistent with this description. For example, if device A provides a signal to control device B to perform an action, then: (a) in a first example, device A is directly coupled to device B; or (b) in a second example, device A is indirectly coupled to device B through intervening component C if intervening component C does not substantially alter the functional relationship between device A and device B, so device B is controlled by device A via the control signal provided by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture by an end-user and/or a third-party.

While certain components may be described herein as being of a particular process technology, these components may be exchanged for components of other process technologies.

Unless otherwise stated, “about,” “approximately,” or “substantially” preceding a value means +/−10 percent of the stated value. Modifications are possible in the described examples, and other examples are possible within the scope of the claims.

What is claimed is:

1. A semiconductor package, comprising:
a semiconductor die configured to detect a force;
a mold compound covering the semiconductor die; and
an engagement surface including a pattern of projections adapted to engage with a mounting surface on a member of interest.

2. The semiconductor package of claim 1, wherein the projections are substantially parallel to one another along the engagement surface.

3. The semiconductor package of claim 2, wherein a first projection of the pattern of projections has a substantially planar crest and a pair of flanks.

4. The semiconductor package of claim 2, wherein the mold compound has an outer perimeter, and the projections are substantially perpendicular to a pair of opposing sides of the outer perimeter along the engagement surface.

5. The semiconductor package of claim 2, wherein the mold compound has an outer perimeter, and the projections are nonparallel to sides of the outer perimeter along the engagement surface and are non-perpendicular to the sides of the outer perimeter along the engagement surface.

6. The semiconductor package of claim 1, wherein the projections are arranged in multiple columns and rows along the engagement surface.

7. The semiconductor package of claim 6, wherein the projections are shaped as truncated pyramids.

8. A semiconductor package, comprising:
a die pad having a first side and a second side opposite the first side; and
a semiconductor die mounted to the first side of the die pad,
the semiconductor die configured to detect a force, and
the second side of the die pad including a pattern of projections that are adapted to engage a pattern of recesses in a mounting surface of a member of interest.

9. The semiconductor package of claim 8, wherein the projections include first and second projections having a rectangular cross-section.

10. The semiconductor package of claim 8, wherein the projections are substantially parallel to one another along the second side of the die pad.

11. The semiconductor package of claim 8, wherein the projections are arranged in multiple rows and columns along the second side of the die pad.

12. The semiconductor package of claim 11, wherein the projections include first and second projections shaped as truncated pyramids.

13. The semiconductor package of claim 8, further comprising a mold compound that covers the die pad and the semiconductor die, the mold compound having an outer perimeter, and the projections including first and second projections that are substantially perpendicular to opposing sides of the outer perimeter.

14. The semiconductor package of claim 8, further comprising a mold compound that covers the die pad and the semiconductor die, the mold compound having an outer perimeter, and the projections include first and second projections that are nonparallel to sides of the outer perimeter and are non-perpendicular to the sides of the outer perimeter.

15. A semiconductor package, comprising:
a die pad;
a semiconductor die mounted to the die pad; and
a mold compound having a first side and a second side opposite the first side, the compound covering the die pad and the semiconductor die, and the second side including a pattern of projections that are adapted to engage with a mounting surface on a member of interest.

16. The semiconductor package of claim 15, wherein the projections are substantially parallel to one another along the engagement surface.

17. The semiconductor package of claim 16, wherein a first projection of the pattern of projections has a substantially planar crest and a pair of flanks.

18. The semiconductor package of claim 16, wherein the mold compound has an outer perimeter, and the projections include first and second projections that are substantially perpendicular to a pair of opposing sides of the outer perimeter along the engagement surface.

19. The semiconductor package of claim 16, wherein the mold compound has an outer perimeter, and the projections include first and second projections that are nonparallel to sides of the outer perimeter along the engagement surface and are non-perpendicular angle to the sides of the outer perimeter along the engagement surface.

20. The semiconductor package of claim 15, wherein the projections are spaced from one another along a radius of an axis extending perpendicularly through the first side and the second side of the mold compound.
